(19) United States
(12) Patent Application Publication
(10) Pub. No.: US 2015/0271925 A1
(43) Pub. Date: Sep. 24, 2015

(54) ELECTRONIC COMPONENT MOUNTING SYSTEM AND ELECTRONIC COMPONENT MOUNTING METHOD

(71) Applicant: PANASONIC INTELLECTUAL PROPERTY MANAGEMENT CO., LTD., Osaka (JP)

(72) Inventors: Taisuke MORI, Yamanashi (JP); Masayuki HIGASHI, Yamanashi (JP)

(21) Appl. No.: 14/629,678

(22) Filed: Feb. 24, 2015

(30) Foreign Application Priority Data
Mar. 20, 2014 (JP) 2014-057465

(51) Int. Cl. H05K 3/30

(52) U.S. Cl. CPC H05K 3/30

(57) ABSTRACT

A component mounting unit includes first and second board conveyance mechanisms, first and second component supply units, and first and second component mounting mechanisms, for performing a component mounting work on a front surface and a rear surface of boards of a same type in parallel. Electronic components of all kinds to be mounted on the front surface and the rear surface at the component mounting unit are distributed to the first and second component supply units. The first and second component mounting mechanisms pick up electronic components from the first and second component supply unit, respectively. The first component mounting mechanism mounts the electronic component on the board held by each of the first and second board conveyance mechanisms. The second component mounting mechanism mounts the electronic component on the board held by each of the first and second board conveyance mechanisms.

### BACKGROUND

1. Technical Field

One or more aspects of the present invention relate to an electronic component mounting system and an electronic component mounting method for mounting an electronic component on a board to manufacture a mounted board.

2. Background Art

An electronic component mounting system for mounting an electronic component on a board to manufacture a mounted board has a structure in which a printing apparatus that prints a paste for soldering and a plurality of component mounting devices that execute component mounting work on the board having undergone the printing are connected. As such an electronic component mounting system, a system is known that has a structure designed for a double-sided mounting board where electronic components are mounted on both front and rear surfaces of the same board (for example, see WO-A1-2005-009100). The related art shown in WO-A1-2005-009100 shows an example where in an electronic circuit production system having a plurality of board carrying conveyors, both front and rear surfaces of the same board type are supplied in mixture and electronic circuit component mounting is executed based on mounting programs adapted for the surfaces, respectively.

### SUMMARY

In recent years, in the electronic industry, further betterment of production efficiency has been requested, and particularly, in production sites of component mounting, improvement in area productivity has been required. However, because of the structure of the electronic circuit production system, the related art such as the WO-A1-2005-009100 does not provide an equipment structure that is most suitable for seeking improvement in area productivity. For example, to better production efficiency, improvement in the operation rate of the mounting head that executes component mounting and minimization of the loss time for board conveyance on the board carrying conveyor are required, and in the conventional equipment designed for the double-sided mounting board, due to the difficulty in line balance because of the difference in mounting load between the front and rear surfaces, it is difficult to realize the above-mentioned requests with compact equipment.

An object of one or more aspects of the present invention is to provide an electronic component mounting system and an electronic component mounting method capable of improving area productivity by improving the operation rate of the mounting head and minimizing the loss time of the board conveyance for double-sided mounting boards.

In a first aspect, there is provided an electronic component mounting system for performing a component mounting work on a front surface and a rear surface of boards of a same type in parallel, said electronic component mounting system including: a component mounting line formed by connecting a plurality of component mounting units that perform the component mounting work to mount an electronic component on a board, wherein at least one of the component mounting units including: a first board conveyance mechanism and a second board conveyance mechanism, each including a board holding unit which conveys a board delivered from an upstream side device in a board conveyance direction and which positions and holds the board; a first component supply unit and a second component supply unit provided to correspond to the first board conveyance mechanism and the second board conveyance mechanism, respectively; and a first component mounting mechanism and a second component mounting mechanism which are provided to correspond to the first board conveyance mechanism and the second board conveyance mechanism, respectively, which pick up electronic components supplied by the first component supply unit and the second component supply unit, respectively, and mounting the electronic components on the board held by the board holding unit, wherein electronic components of all kinds to be mounted on the front surface and the rear surface at the own component mounting unit are distributed to the first component supply unit and the second component supply unit, wherein the first component mounting mechanism picks up an electronic component from the first component supply unit, and mounts the electronic component on the board held by the board holding unit of each of the first board conveyance mechanism and the second board conveyance mechanism, and wherein the second component mounting mechanism picks up an electronic component from the second component supply unit, and mounts the electronic component on the board held by the board holding unit of each of the first board conveyance mechanism and the second board conveyance mechanism.

In a second aspect, there is provided an electronic component mounting method for performing a component mounting work on a front surface and a rear surface of boards of a same type in parallel by an electronic component mounting system including a component mounting line formed by connecting a plurality of component mounting units that perform the component mounting work to mount an electronic component on a board, wherein at least one of the component mounting units including: a first board conveyance mechanism and a second board conveyance mechanism, each including a board holding unit which conveys a board delivered from an upstream side device in a board conveyance direction and which positions and holds the board; a first component supply unit and a second component supply unit provided to correspond to the first board conveyance mechanism and the second board conveyance mechanism, respectively; and a first component mounting mechanism and a second component mounting mechanism which are provided to correspond to the first board conveyance mechanism and the second board conveyance mechanism, respectively, which pick up electronic components supplied by the first component supply unit and the second component supply unit, respectively, and mounting the electronic components on the board held by the board holding unit, wherein electronic components of all kinds to be mounted on the front surface and the rear surface at the own component mounting unit are distributed to the first component supply unit and the second component supply unit, said electronic component mounting method including: controlling the first component mounting mechanism to pick up an electronic component from the first component supply unit, and to mount the electronic component on the board held by the board holding unit of each of the first board conveyance mechanism and the second board conveyance mechanism; and controlling the second component mounting mechanism to pick up an electronic component from the second component supply unit, and to mount the electronic component on the board held by the board holding unit of each of the first board conveyance mechanism and the second board conveyance mechanism.

According to one or more aspects of the present invention, it is possible to improve area productivity by improving the operation rate of the mounting head and to minimize the loss time of the board conveyance for double-sided mounting boards.

### BRIEF DESCRIPTION OF THE DRAWINGS

FIG. 1 is a structure explanation view of an electronic component mounting system of an embodiment of the present invention;

FIGS. 2A and 2B are explanation views of a board on which the work of the electronic component mounting system of the embodiment of the present invention is to be performed;

FIG. 3 is a structure explanation view of component mounting lines in the electronic component mounting system of the embodiment of the present invention;

FIG. 4 is a block diagram showing the structure of a control system of the component mounting lines in the electronic component mounting system of the embodiment of the present invention;

FIGS. 5A and 5B are explanation views of mounting work modes in the component mounting lines of the embodiment of the present invention;

FIG. 6 is an explanation view of a shared feeder arrangement in the component mounting lines of the embodiment of the present invention;

FIGS. 7A to 7C are process explanation views of a component mounting method by the component mounting lines of the embodiment of the present invention;

FIG. 8 is a structure explanation view of the component mounting lines in the electronic component mounting system of the embodiment of the present invention;

FIGS. 9A to 9C are process explanation views of the component mounting method by the electronic component mounting lines of the embodiment of the present invention; and

FIGS. 10A and 10B are process explanation views of the component mounting method by the electronic component mounting lines of the embodiment of the present invention.

### DETAILED DESCRIPTION

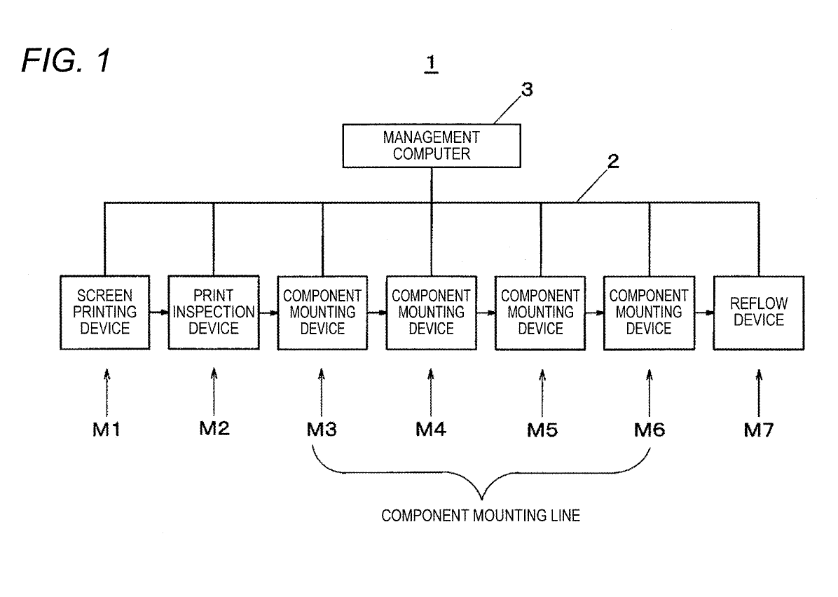

Next, an embodiment of the present invention will be described with reference to the drawings. First, referring to FIG. 1, the structure of an electronic component mounting system 1 will be described. The electronic component mounting system 1 has the function of performing component mounting work on the front and rear surfaces of boards of a same type in parallel, thereby producing a mounted board by mounting electronic components on a board by soldering. To execute this component mounting work, the electronic component mounting system 1 is formed by connecting a plurality of component mounting devices. The plurality of component mounting devices includes a screen printing device M1, a print inspection device M2, component mounting devices M3, M4, M5 and M6 and a reflow device M7. The devices M1-M7 are connected by a communication network 2 such that the whole thereof is managed by a management computer 3.

The screen printing device M1 screen-prints a solder paste such as cream solder on electrodes for component bonding formed on a board. The print inspection device M2 determines whether the printing condition of the solder printed on the board is good or not and performs print inspections including the detection of a print position displacement of the solder from the electrode. The component mounting devices M3, M4, M5 and M6 are each a component mounting unit that performs component mounting work to mount an electronic component on the board, and a component mounting line is formed by coupling these plurality of component mounting units. By this component mounting line, electronic components are successively mounted on the board where the solder is printed by the screen printing device M1. The reflow device M7 melts the solder by heating the board having the electronic components mounted thereon according to a predetermined temperature profile, thereby soldering the electronic components to the board.

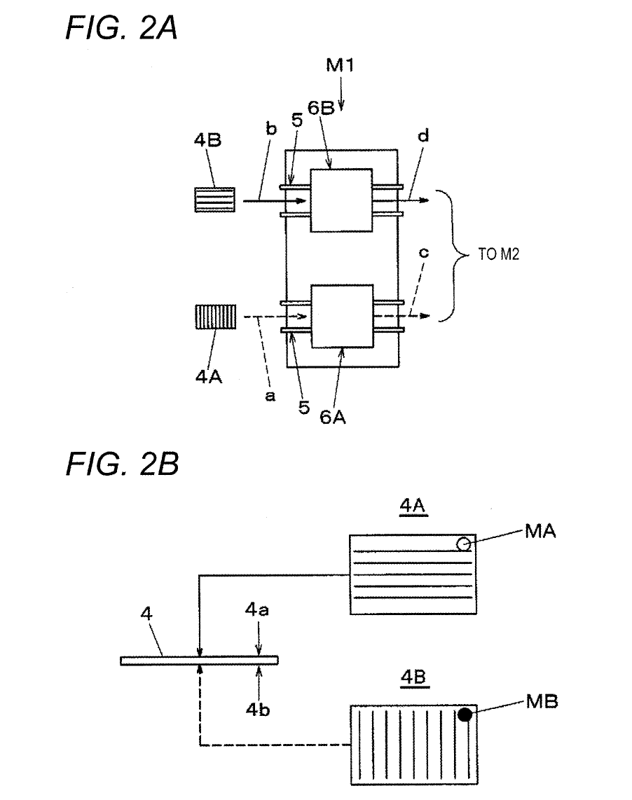

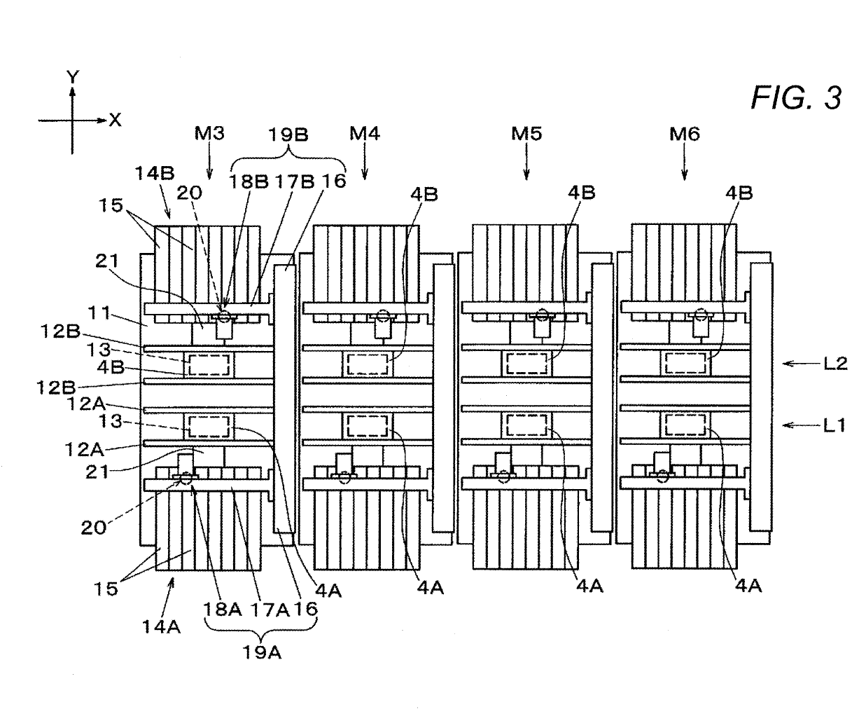

Next, referring to FIGS. 2A and 2B, the board on which the component mounting work by the electronic component mounting system 1 is to be performed and the board supply mode will be described. As shown in FIG. 2A, the screen printing device Ml has a structure in which two first screen printing unit 6A and second screen printing unit 6B are disposed in parallel. Boards 4A and 4B on which screen printing is to be performed are carried into the first screen printing unit 6A and the second screen printing unit 6B through carrying conveyors 5, respectively (arrows a and b). The boards 4A and 4B having undergone screen printing are carried out by the carrying conveyors 5 (arrows c and d), delivered to the print inspection device M2 where predetermined inspections are performed thereon, and then, carried into the component mounting lines shown in FIG. 3.

Here, the boards 4A and 4B are, as shown in FIG. 2B, the mounting surfaces of the front surface 4a and the rear surface 4b of the same board 4, and in the following description, for the sake of convenience, the mounting surfaces corresponding to the front surface 4a and the rear surface 4b will be referred to as the boards 4A and 4B, respectively. On the boards 4A and 4B, recognition marks MA and MB for identification are formed in advance, respectively, and by imaging and recognizing these recognition marks MA and MB, it can be identified whether the mounting surface on which the work is to be performed corresponds to the board 4A or the board 4B.

While a screen printing device having two screen printing units is used in the present embodiment, two screen printing devices each having one screen printing unit may be disposed in the conveyance direction.

Next, referring to FIG. 3, the component mounting lines formed by coupling the component mounting devices M3, M4, M5 and M6 as the component mounting units will be described. The component mounting devices M3, M4, M5 and M6 have a first mounting lane L1 and a second mounting lane L2 disposed in parallel, and by these two lanes, the component mounting work can be performed on the boards 4A and 4B in parallel.

Hereinafter, the structure of each component mounting device as the component mounting unit will be described. Since the component mounting devices M3, M4, M5 and M6 have the same structure, reference numerals are assigned only to the component mounting device M3 here. In the center of a base 11, a first board conveyance mechanism 12A and a second board conveyance mechanism 12B forming the first mounting lane L1 and the second mounting lane L2 are disposed in parallel in the X direction (board conveyance direction). The first board conveyance mechanism 12A and the second board conveyance mechanism 12B which are each provided with a board holding unit 13 convey the board delivered from the upstream side device in the X direction, position it and hold it by the board holding unit 13.

On the outer sides of the first board conveyance mechanism 12A and second board conveyance mechanism 12B, a first component supply unit 14A and a second component supply unit 14B are disposed corresponding to the first board conveyance mechanism 12A and the second board conveyance mechanism 12B, respectively, and in the first component supply unit 14A and the second component supply unit 14B, a plurality of tape feeders 15 are disposed in parallel. The tape feeders 15 pitch-feed a carrier tape that is holding components to be mounted, thereby supplying the electronic components to the position at which the electronic components are to be picked up by the component mounting mechanism described later.

On an end portion on the downstream side in the X direction of the upper surface of the base 11, a Y-axis movement table 16 is disposed in the Y direction. To the Y-axis movement table 16, a first X-axis movement table 17A and a second X-axis movement table 17B are attached. The first X-axis movement table 17A and the second X-axis movement table 17B are slidable in the Y direction along the side surface of the Y-axis movement table 16, and are driven in the Y direction by a linear motor mechanism incorporated in the Y-axis movement table 16.

To the first X-axis movement table 17A and the second X-axis movement table 17B, a first mounting head 18A and a second mounting head 18B are attached through X-axis movement attachment bases, respectively. The first mounting head 18A and the second mounting head 18B are driven in the X direction by linear motor mechanisms incorporated in the first X-axis movement table 17A and the second X-axis movement table 17B. The Y-axis movement table 16, the first X-axis movement table 17A and the second X-axis movement table 17B serve as a head moving mechanism for moving the first mounting head 18A and the second mounting head 18B.

The first mounting head 18A and the second mounting head 18B have a structure in which a plurality of suction nozzles (not shown) are detachably attached to lower parts thereof, are moved by the above-mentioned head moving mechanism, pick up the electronic components to be mounted by the suction nozzles from the tape feeders 15 of the first component supply unit 14A and the second component supply unit 14B, and transfer and mount them on the boards 4A and 4B.

The first mounting head 18A, the first X-axis movement table 17A and the Y-axis movement table 16 constitute a first component mounting mechanism 19A that is provided corresponding to the first board conveyance mechanism 12A, picks up the electronic component supplied by the first component supply unit 14A and mounts it on the boards 4A and 4B held by the board holding units 13 of the first board conveyance mechanism 12A and the second board conveyance mechanism 12B. Moreover, the second mounting head 18B, the second X-axis movement table 17B and the Y-axis movement table 16 constitute a second component mounting mechanism 19B that is provided corresponding to the second board conveyance mechanism 12B, picks up the electronic component supplied by the second component supply unit 14B and mounts it on the boards 4A and 4B held by the board holding units 13 of the first board conveyance mechanism 12A and the second board conveyance mechanism 12B.

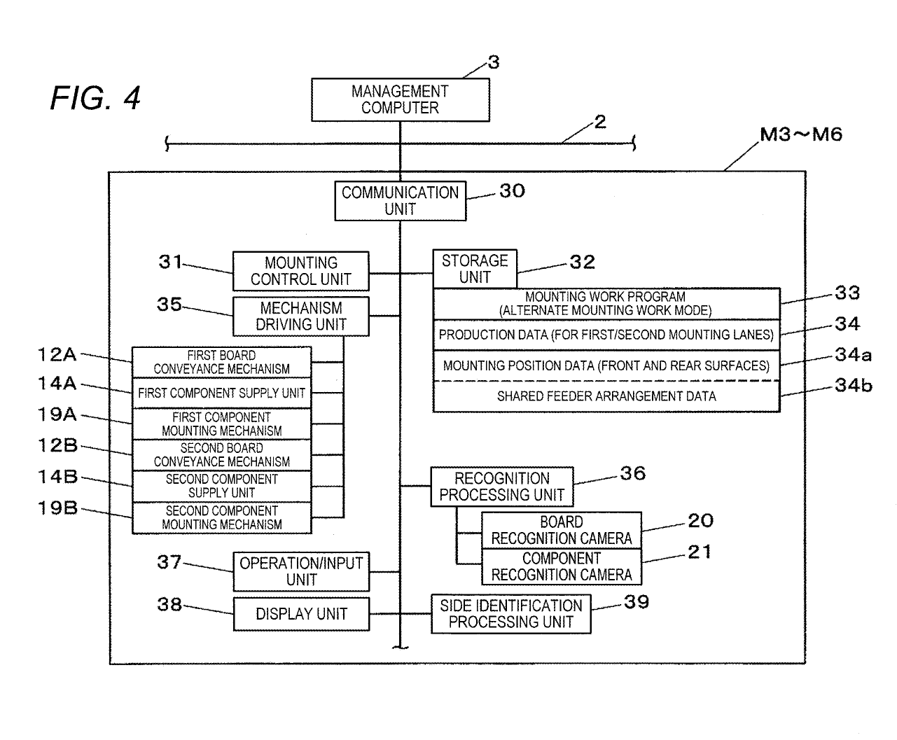

Between each of the first board conveyance mechanism 12A and the second board conveyance mechanism 12B and the tape feeders 15, a component recognition camera 21 is disposed. The component recognition cameras 21 are situated on the movement paths of the first mounting head 18A and the second mounting head 18B, and image the electronic components held by the first mounting head 18A and the second mounting head 18B from below. By performing recognition processing on the result of the imaging by a recognition processing unit 36 (see FIG. 4), position displacements of the electronic components in a state of being held by the first mounting head 18A and the second mounting head 18B are detected.

To the first mounting head 18A and the second mounting head 18B, board recognition cameras 20 moved integrally with the first mounting head 18A and the second mounting head 18B by the above-mentioned head moving mechanism are attached. The board recognition cameras 20 move to above the boards 4A and 4B held by the first board conveyance mechanism 12A and the second board conveyance mechanism 12B together with the first mounting head 18A and the second mounting head 18B, and image the boards 4A and 4B. By performing recognition processing on the result of the imaging, the positions of the boards 4A and 4B are detected, and the recognition marks MA and MB formed on the boards 4A and 4B are recognized. Thereby, it is identified whether the board 4 carried into the first board conveyance mechanism 12A and the second board conveyance mechanism 12B corresponds to the board 4A or the board 4B, and based on the result of the identification, the component mounting work adapted for the board 4A or the board 4B is executed. Then, on the boards 4A and 4B having undergone the component mounting work, the electronic components sent to the reflow device M7 are mounted and soldered.

Next, referring to FIG. 4, the structure of the control system of the component mounting lines in the electronic component mounting system 1 will be described. In FIG. 4, the component mounting devices M3 to M6 are provided with a communication unit 30, a mounting control unit 31, a storage unit 32, a mechanism driving unit 35, a recognition processing unit 36, an operation/input unit 37, a display unit 38 and a side identification processing unit 39. The communication unit 30 is connected to the management computer 3 and other devices included in the electronic component mounting system 1 through the communication network 2, and performs control signal transmission and reception with these devices. The mounting control unit 31 is a CPU device having a control calculation function, and controls the following units based on various kinds of programs and data such as a mounting work program 33 and production data 34 stored in the storage unit 32.

The production data 34 is various kinds of data used for the component mounting work executed at the first mounting lane L1 and the second mounting lane L2 of the component mounting device, and is prestored for each of the target board types. These pieces of data include mounting position data 34a storing the mounting coordinates of the electronic components to be mounted on the boards for each of the boards 4A and 4B and shared feeder arrangement data 34b indicative of the kinds of the tape feeders 15 disposed in the first component supply unit 14A and the second component supply unit 14B of the component mounting unit for supplying these electronic components.

The mechanism driving unit 35 drives the first board conveyance mechanism 12A, the first component supply unit 14A, the first component mounting mechanism 19A, the second board conveyance mechanism 12B, the second component supply unit 14B and the second component mounting mechanism 19B by being controlled by the mounting control unit 31. Thereby, the component mounting work at each component mounting device is executed. The recognition processing unit 36 performs recognition processing on the result of the imaging by the board recognition cameras 20 and the component recognition cameras 21. Thereby, the positions of the board 4A and the board 4B are recognized and the position displacements of the electronic components in a state of being held by the first mounting head 18A and the second mounting head 18B are detected.

The operation/input unit 37 is an input device such as a touch panel device incorporated in the display unit 38, and performs the processing of inputting various kinds of data in addition to operation commands to the component mounting devices. The display unit 38 is a display device such as a liquid crystal panel, and displays a screen for imaging by the board recognition cameras 20 and the component recognition cameras 21, a guide screen for the time of the operation by the operation/input unit 37, and the like. The side identification processing unit 39 identifies whether the board surface on which the work is to be performed corresponds to the board 4A or the board 4B based on the result of the imaging, by the board recognition cameras 20, of the board surfaces where the recognition marks MA and MB are formed.

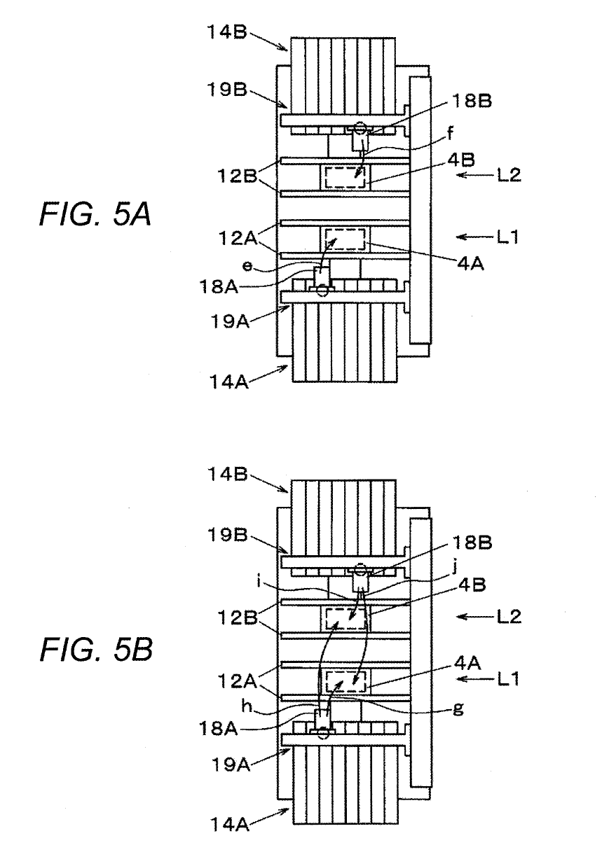

Now, referring to FIGS. 5A and 5B, work modes will be described of the component mounting work executed in the device structure having two board conveyance mechanisms and two mounting heads corresponding thereto, respectively, like the component mounting devices M3 to M6 shown in the present embodiment. FIG. 5A shows a so-called independent mounting mode in which on the boards 4 (4A, 4B) conveyed by the first board conveyance mechanism 12A and the second board conveyance mechanism 12B, the component mounting operation is executed only by the corresponding first mounting head 18A and second mounting head 18B. That is, the first mounting head 18A picks up an electronic component from the first component supply unit 14A and mounts it on the board 4A positioned by the first board conveyance mechanism 12A (arrow e), and the second mounting head 18B picks up an electronic component from the second component supply unit 14B and mounts it on the board 4 positioned by the second board conveyance mechanism 12B (arrow f).

On the contrary, FIG. 5B shows a so-called alternate mounting work mode in which on the boards 4 (4A, 4B) conveyed by the first board conveyance mechanism 12A and the second board conveyance mechanism 12B, an electronic component is mounted alternately by the first mounting head 18A and the second mounting head 18B. That is, the first mounting head 18A picks up electronic components from the first component supply unit 14A, and mounts them on the board 4A positioned by the first board conveyance mechanism 12A (arrow g) and on the board 4B positioned by the second board conveyance mechanism 12B (arrow h). Moreover, the second mounting head 18B picks up electronic components from the second component supply unit 14B, and mounts them on the board 4A positioned by the first board conveyance mechanism 12A (arrow j) and on the board 4B positioned by the second board conveyance mechanism 12B (arrow i).

According to the component mounting method by the electronic component mounting system 1 of the present embodiment, by applying the above-described alternate mounting work mode to the component mounting work executed on the front and rear surfaces of the boards of the same type in parallel, improvement in the operation rate of the mounting heads and reduction in the loss time for board conveyance on the board conveyance mechanisms are achieved.

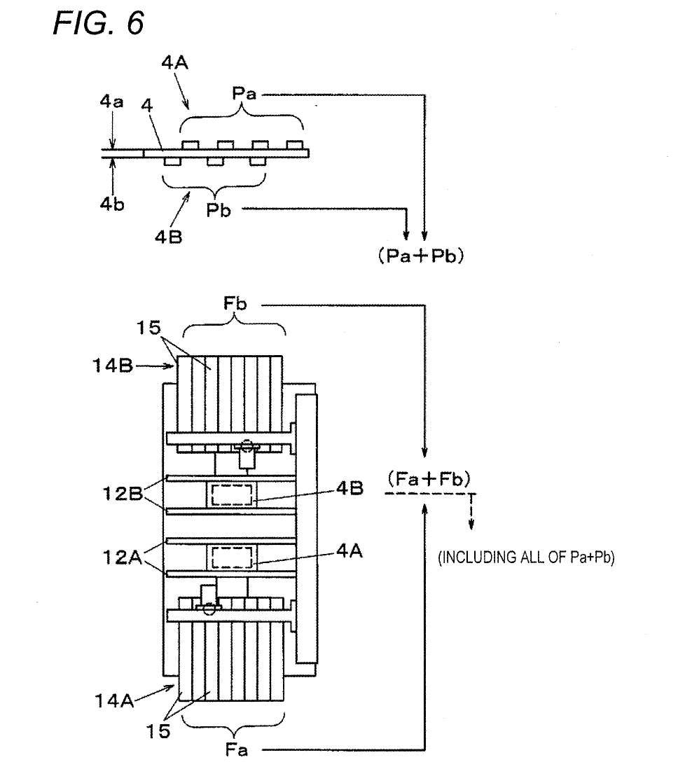

Next, referring to FIG. 6, the shared feeder arrangement data 34b stored in the storage unit 32 will be described. Here is shown a relation between the kinds of electronic components to be mounted on the front surface 4a and the rear surface 4b of the board 4 by each component mounting device and the mode of arrangement of the tape feeders 15 in the first component supply unit 14A and the second component supply unit 14B of each component mounting device in the component mounting devices constituting the component mounting line.

In FIG. 6, on the board 4A and the board 4B corresponding to the front surface 4a and the rear surface 4b of the board 4, one or more electronic components are mounted at the component mounting device. These electronic components constitute sets (Pa) and (Pb). That is, in the component mounting device, electronic components constituting a set (Pa+Pb) are mounted on the board 4 having the board 4A and the board 4B.

Moreover, (Fa) and (Fb) shown corresponding to the first component supply unit 14A and the second component supply unit 14B in FIG. 6 represent sets of the tape feeders 15 attached to the first component supply unit 14A and the second component supply unit 14B, respectively. That is, to the component mounting device, the tape feeders 15 constituting a set (Fa+Fb) are attached. Here, the kinds of the electronic components accommodated in the tape feeders 15 constituting the set (Fa+Fb) include electronic components of all the kinds constituting the set (Pa+Pb), and the electronic components required for the component mounting work adapted for the board 4A and the board 4B can be supplied by either of the first component supply unit 14A and the second component supply unit 14B.

In other words, a plurality of tape feeders 15 accommodating electronic component of all the kinds to be mounted on the front surface 4a and the rear surface 4b of the board 4 in the component mounting device are distributed to the first component supply unit 14A and the second component supply unit 14B, and in the shared feeder arrangement data 34b, feeder arrangement data conforming to this arrangement mode is stored. By adopting this feeder arrangement, in a case where two mounting surfaces such as the front and rear surfaces of the same board between which an imbalance in the number of mounted components is present are the target of the work in the same device, the feeder arrangement capacities of the first component supply unit 14A and the second component supply unit 14B can be effectively utilized. Consequently, the feeder arrangement capability required for the component mounting device is reduced as much as possible to realize downsizing of the device, so that area productivity can be improved.

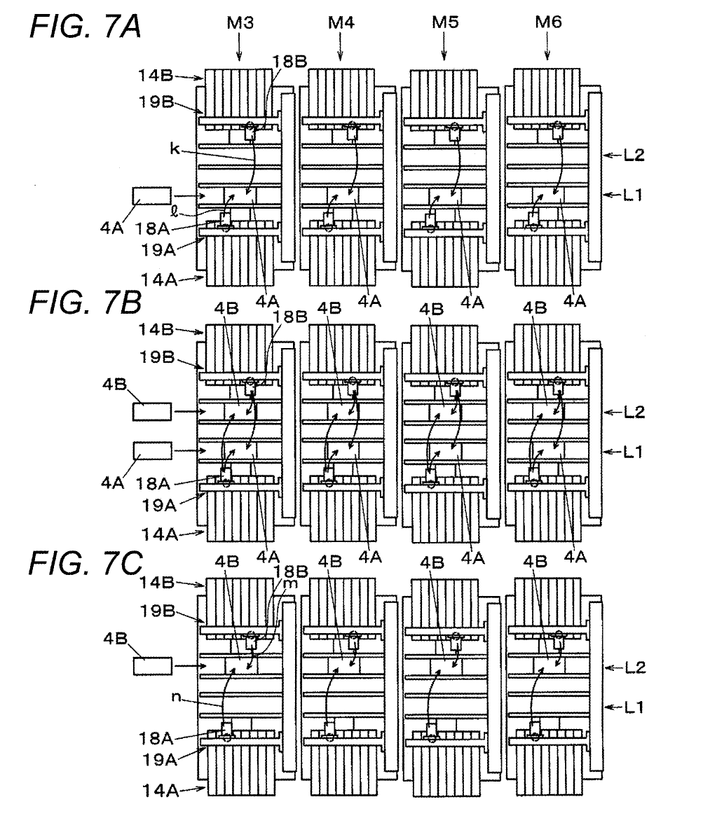

Next, referring to FIGS. 7A to 7C, the component mounting method by the electronic component mounting system 1 will be described. Here is shown the component mounting operation at each device when the component mounting work is executed on the board 4A corresponding to the front surface 4a and the board 4B corresponding to the rear surface 4b of the same board type in the above-described component mounting lines.

First, at the time of start-up immediately after the start of the component mounting work, since the production of only the board 4A corresponding to the front surface 4a precedes in the preceding process, as shown in FIG. 7A, the boards 4A are continuously carried into the first mounting lane L1. Then, at each of the component mounting devices M3 to M6, the component mounting operation by the first component mounting mechanism 19A and the component mounting operation by the second component mounting mechanism 19B are alternately executed on the board 4A positioned and held in the first mounting lane L1. That is, the first mounting head 18A picks up an electronic component from the first component supply unit 14A and mounts it on the board 4A positioned in the first mounting lane L1 (arrow l), and the second mounting head 18B picks up an electronic component from the second component supply unit 14B and mounts it on the board 4A positioned in the first mounting lane L1 (arrow k).

Then, when the board 4B corresponding to the rear surface 4b comes to be produced in parallel with the board 4A in the preceding process, the condition is shifted to a regular production condition where the component mounting work is performed on the board 4A and the board 4B in parallel. In this regular production condition, as shown in FIG. 7B, the boards 4A and the boards 4B are continuously carried into the first mounting lane L1 and the second mounting lane L2, respectively. Then, at each of the component mounting devices M3 to M6, the component mounting operation in the alternate mounting work mode (see FIG. 5B) by both the first component mounting mechanism 19A and the second component mounting mechanism 19B is executed on the boards 4A and the boards 4B positioned and held in the first mounting lane L1 and the second mounting lane L2, respectively.

That is, the first mounting head 18A picks up an electronic component from the first component supply unit 14A, mounts it on the board 4A positioned in the first mounting lane L1 and mounts an electronic component on the board 4B positioned in the second mounting lane L2. Moreover, the second mounting head 18B picks up an electronic component from the second component supply unit 14B and mounts it on the board 4A positioned in the first mounting lane L1, and mounts an electronic component on the board 4B positioned in the second mounting lane L2.

Thereafter, when the production of a predetermined number of boards 4A is finished and the regular production condition is completed, the condition is shifted to a condition for ending the lot. Under this condition, as shown in FIG. 7C, the boards 4B are continuously carried into the second mounting lane L2, and at each of the component mounting devices M3 to M6, the component mounting operation by both the first component mounting mechanism 19A and the second component mounting mechanism 19B is executed on the boards 4B positioned and held in the second mounting lane L2.

In the above-described component mounting method, in the regular production condition shown in FIG. 7B, beneficial effects as mentioned below are obtained stemming from the adopted mounting work mode. Here, the component mounting operation in the alternate mounting work mode by both the first component mounting mechanism 19A and the second component mounting mechanism 19B is executed on the board 4A and the board 4B positioned and held in the first mounting lane L1 and the second mounting lane L2, respectively.

That is, during the board conveyance operation for carrying out, to the downstream side device, the board 4A having undergone the component mounting work in the mounting lane on one side of the device, the component mounting operation on the board 4 positioned and held by the mounting lane on the other side is also executed without the component mounting mechanism corresponding to the mounting lane on the one side stopping the work operation. Thereby, the two component mounting mechanisms can also continuously perform the component mounting operation while the board conveyance operation is being performed on either of the two mounting lanes, so that the occurrence of the loss time due to an operation halt attributable to board conveyance is avoided to enable betterment of the operation rate of the equipment and improvement in productivity.

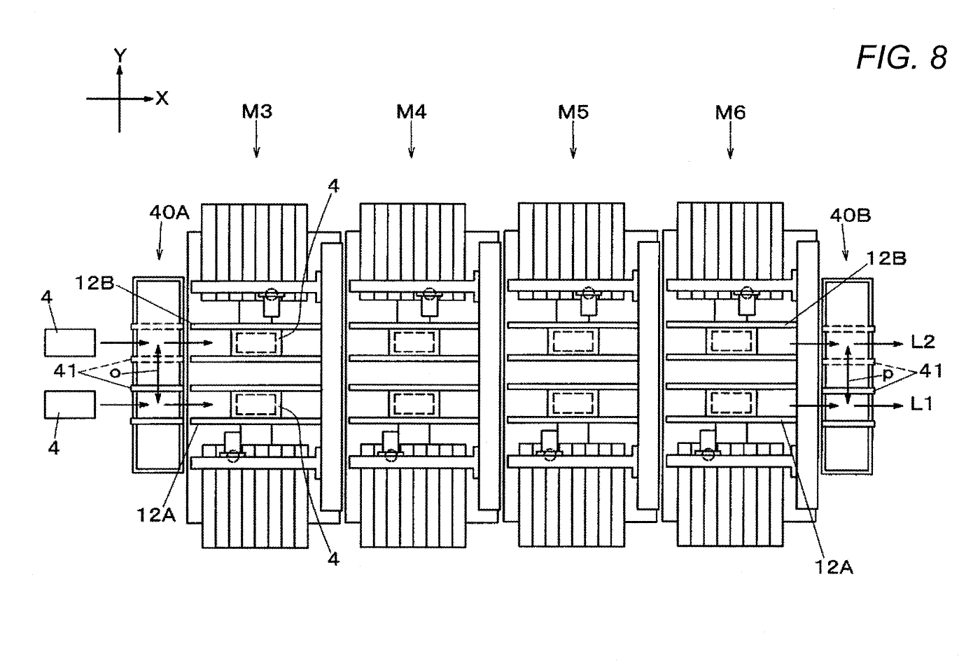

FIG. 8 shows a structural example having a board selective delivering means for selectively delivering the board 4 between the first mounting lane L1 and the second mounting lane L2 in the component mounting lines constituted by the component mounting devices M3 to M6 shown in FIG. 3. In FIG. 8, on the upstream side of the component mounting device M3 and the downstream side of the component mounting device M6, board selective delivering devices 40A and 40B as board selective delivering means are disposed, respectively. The board selective delivering devices 40A and 40B are both slidable between the first mounting lane L1 and the second mounting lane L2 in the Y direction (arrows o and p), and have a conveyer mechanism 41 that can be connected to both of the first board conveyance mechanism 12A and the second board conveyance mechanism 12B.

By the structure having the board selective delivering device 40A, the board 4 received at any position in the first mounting lane L1 or the second mounting lane L2 from the upstream side device can be delivered to either the first board conveyance mechanism 12A or the second board conveyance mechanism 12B. Moreover, by the structure having the board selective delivering device 40B, the board 4 carried out from either the first board conveyance mechanism 12A or the second board conveyance mechanism 12B can be delivered to any position in the first mounting lane L1 or the second mounting lane L2 and delivered to the downstream side device.

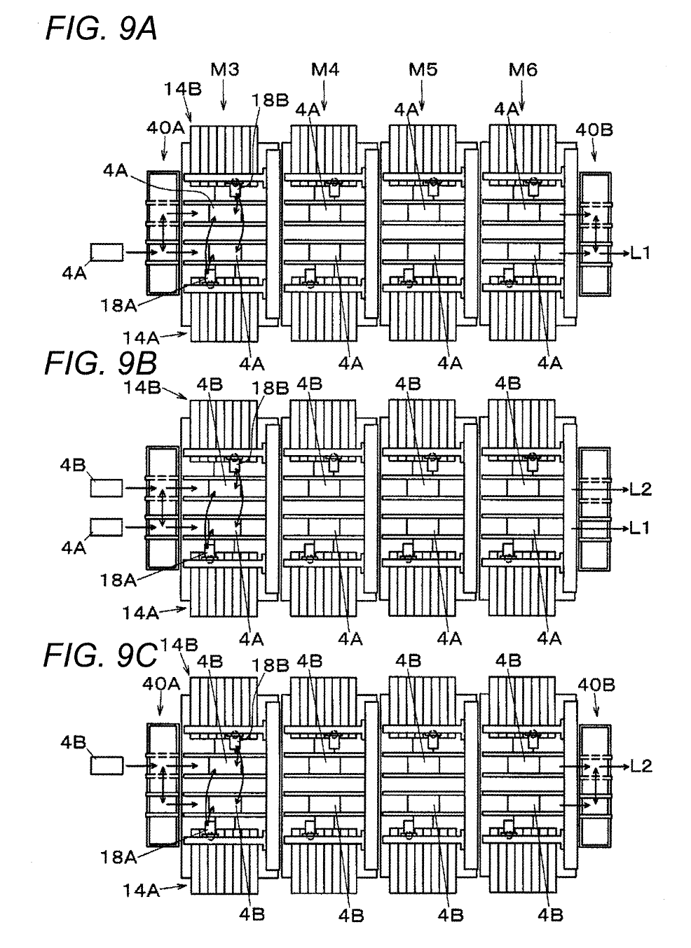

Next, the component mounting method by the component mounting lines of the structure having the board selective delivering means shown in FIG. 8 will be described with reference to FIGS. 9A to 9C. As in FIG. 7, here is also shown the component mounting operation at each device when the component mounting work is executed on the board 4A corresponding to the front surface 4a and the board 4B corresponding to the rear surface 4b of the same board type in the above-described component mounting lines.

First, at the time of start-up immediately after the start of the component mounting work, since the production of only the board 4A corresponding to the front surface 4a precedes in the preceding process, as shown in FIG. 9A, the boards 4A are continuously carried into the first mounting lane L1. Here, the boards 4A carried into the first mounting lane L1 are alternately delivered to the first mounting lane L1 and the second mounting lane L2 by the board selective delivering device 40A, and at each of the component mounting devices M3 to M6, the component mounting operation by the first component mounting mechanism 19A and the component mounting operation by the second component mounting mechanism 19B are alternately performed on the two boards 4A positioned and held in the first mounting lane L1 and the second mounting lane L2.

That is, the first mounting head 18A picks up electronic components from the first component supply unit 14A and mounts them on the two boards 4A positioned in the first mounting lane L1 and the second mounting lane L2, and the second mounting head 18B picks up electronic components from the second component supply unit 14B and mounts them on the two boards 4A positioned in the first mounting lane L1 and the second mounting lane L2.

Then, when the board 4B corresponding to the rear surface 4b comes to be produced in parallel with the board 4A in the preceding process, the condition is shifted to the regular production condition where the component mounting work is performed on the board 4A and the board 4B in parallel. In this regular production condition, as shown in FIG. 9B, the boards 4A and the boards 4B are continuously carried into the first mounting lane L1 and the second mounting lane L2, respectively. Then, at each of the component mounting devices M3 to M6, as in the example shown in FIG. 7B, the component mounting operation in the alternate mounting work mode by both the first component mounting mechanism 19A and the second component mounting mechanism 19B is executed on the boards 4A and the boards 4B positioned and held in the first mounting lane L1 and the second mounting lane L2, respectively.

Thereafter, when the production of a predetermined number of boards 4A is finished and the regular production condition is completed, the condition is shifted to the condition for ending the lot. Under this condition, as shown in FIG. 9C, the boards 4B are continuously carried into the second mounting lane L2. Here, the boards 4B carried into the second mounting lane L2 are alternately delivered to the first mounting lane L1 and the second mounting lane L2 by the board selective delivering device 40B, and at each of the component mounting devices M3 to M6, the component mounting operation by both the first component mounting mechanism 19A and the second component mounting mechanism 19B are performed on the two boards 4B positioned and held in the first mounting lane L1 and the second mounting lane L2. By the above-described component mounting method, effects similar to those of the example shown in FIGS. 7A to 7C can also be obtained.

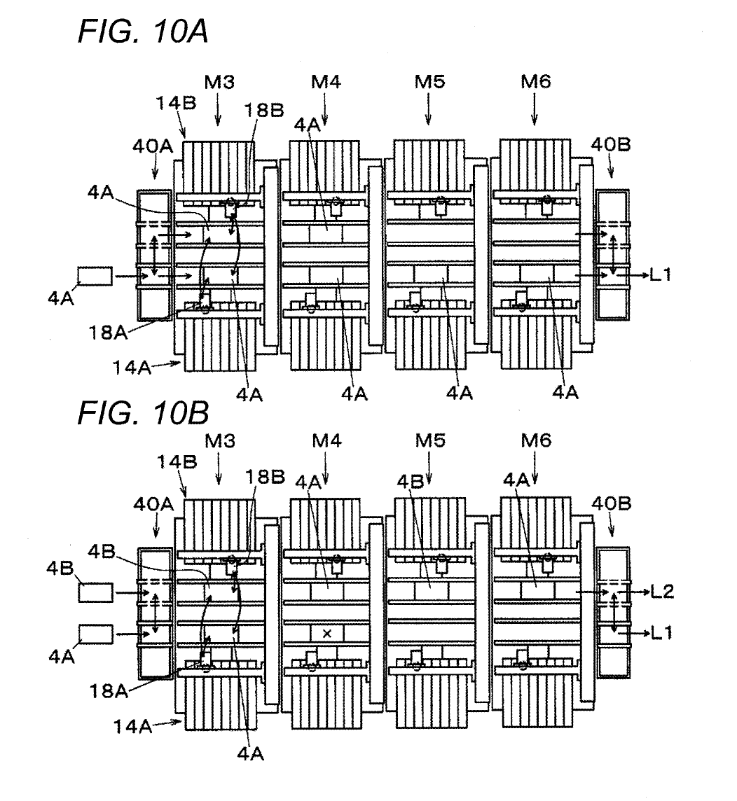

By providing the board selective delivering means shown in FIG. 8, unforeseen situations that occur in the regular production process shown in FIG. 8A can be flexibly handled. For example, FIG. 10A shows a situation in which the supply of the board 4B to the second mounting lane L2 is interrupted by a trouble occurring in the upstream side device. In such a case, the boards 4A carried into the first mounting lane L1 are alternately delivered to the first mounting lane L1 and the second mounting lane L2 by the board selective delivering device 40A, and at each of the component mounting devices M3 to M6, the component mounting operation is alternately executed by the first mounting head 18A and the second mounting head 18B on the two boards 4A positioned and held in the first mounting lane L1 and the second mounting lane L2. Thereby, the component mounting function of the second mounting lane L2 where board supply is stopped is never idled, so that the device operation rate can be maintained.

The example shown in FIG. 10B shows a condition where a board jam is occurring due to a device trouble in either of the two mounting lanes (in this example, the component mounting device M4 in the first mounting lane L1). In such a case, since no boards can be supplied to the first mounting lane L1 on the downstream side from the component mounting device M4, the work to be performed on the board 4A as the target of the work in the first mounting lane L1 is interrupted. In such a case, the boards 4A continuously carried into the first mounting lane L1 are alternately delivered also to the side of the second mounting lane L2 by the board selective delivering device 40A. Thereby, the work can be performed on the board 4A and the board 4B only by the second mounting lane L2 without the use of the first mounting lane L1 where the work is interrupted. Consequently, although the throughput is reduced, the production of the board type where the board 4A and the board 4B are a pair is not stopped, so that the influence of a device trouble on the production plan can be minimized.

The electronic component mounting system and the electronic component mounting method of one or more aspects of the present invention produce an advantageous effect of improving the operation rate of the mounting head and minimizing the loss time of the board conveyance for double-sided mounting boards to thereby improve area productivity, and is useful in the field of electronic component mounting where electronic components are mounted on a board to manufacture a mounted board.

What is claimed is:

1. An electronic component mounting system for performing a component mounting work on a front surface and a rear surface of boards of a same type in parallel, said electronic component mounting system comprising:
a component mounting line formed by connecting a plurality of component mounting units that perform the component mounting work to mount an electronic component on a board,
wherein at least one of the component mounting units comprising:
a first board conveyance mechanism and a second board conveyance mechanism, each comprising a board holding unit which conveys a board delivered from an upstream side device in a board conveyance direction and which positions and holds the board;
a first component supply unit and a second component supply unit provided to correspond to the first board conveyance mechanism and the second board conveyance mechanism, respectively; and
a first component mounting mechanism and a second component mounting mechanism which are provided to correspond to the first board conveyance mechanism and the second board conveyance mechanism, respectively, which pick up electronic components supplied by the first component supply unit and the second component supply unit, respectively, and mounting the electronic components on the board held by the board holding unit,
wherein electronic components of all kinds to be mounted on the front surface and the rear surface at the own component mounting unit are distributed to the first component supply unit and the second component supply unit,
wherein the first component mounting mechanism picks up an electronic component from the first component supply unit, and mounts the electronic component on the board held by the board holding unit of each of the first board conveyance mechanism and the second board conveyance mechanism, and
wherein the second component mounting mechanism picks up an electronic component from the second component supply unit, and mounts the electronic component on the board held by the board holding unit of each of the first board conveyance mechanism and the second board conveyance mechanism.

2. The electronic component mounting system according to claim 1,
wherein the component mounting line comprises a board selective delivering device which selectively delivers the board received from the upstream side device to one of the first board conveyance mechanism and the second board conveyance mechanism.

3. An electronic component mounting method for performing a component mounting work on a front surface and a rear surface of boards of a same type in parallel by an electronic component mounting system comprising a component mounting line formed by connecting a plurality of component mounting units that perform the component mounting work to mount an electronic component on a board,
wherein at least one of the component mounting units comprising:
a first board conveyance mechanism and a second board conveyance mechanism, each comprising a board holding unit which conveys a board delivered from an upstream side device in a board conveyance direction and which positions and holds the board;
a first component supply unit and a second component supply unit provided to correspond to the first board conveyance mechanism and the second board conveyance mechanism, respectively; and
a first component mounting mechanism and a second component mounting mechanism which are provided to correspond to the first board conveyance mechanism and the second board conveyance mechanism, respectively, which pick up electronic components supplied by the first component supply unit and the second component supply unit, respectively, and mounting the electronic components on the board held by the board holding unit,
wherein electronic components of all kinds to be mounted on the front surface and the rear surface at the own component mounting unit are distributed to the first component supply unit and the second component supply unit,
said electronic component mounting method comprising:
controlling the first component mounting mechanism to pick up an electronic component from the first component supply unit, and to mount the electronic component on the board held by the board holding unit of each of the first board conveyance mechanism and the second board conveyance mechanism; and
controlling the second component mounting mechanism to pick up an electronic component from the second component supply unit, and to mount the electronic component on the board held by the board holding unit of each of the first board conveyance mechanism and the second board conveyance mechanism.

4. The electronic component mounting method according to claim 3, further comprising:
selectively delivering the board received from an upstream side device to one of the first board conveyance mechanism and the second board conveyance mechanism.
